(19) United States
(12) Patent Application Publication
(10) Pub. No.: US 2013/0068161 A1
(43) Pub. Date: Mar. 21, 2013

(54) GAS DELIVERY AND DISTRIBUTION FOR UNIFORM PROCESS IN LINEAR-TYPE LARGE-AREA PLASMA REACTOR

(71) Applicants: John M. White, Hayward, CA (US); Suhail Anwar, Saratoga, CA (US); Jozef Kudela, San Jose, CA (US); Carl A. Sorensen, Morgan Hill, CA (US); Tae K. Won, San Jose, CA (US); Seon-Mee Cho, Santa Clara, CA (US); Soo Young Choi, Fremont, CA (US); Beom Soo Park, San Jose, CA (US); Benjamin M. Johnston, Los Gatos, CA (US)

(72) Inventors: John M. White, Hayward, CA (US); Suhail Anwar, Saratoga, CA (US); Jozef Kudela, San Jose, CA (US); Carl A. Sorensen, Morgan Hill, CA (US); Tae K. Won, San Jose, CA (US); Seon-Mee Cho, Santa Clara, CA (US); Soo Young Choi, Fremont, CA (US); Beom Soo Park, San Jose, CA (US); Benjamin M. Johnston, Los Gatos, CA (US)

(73) Assignee: Applied Materials, Inc., Santa Clara, CA (US)

(21) Appl. No.: 13/538,389

(22) Filed: Jun. 29, 2012

Related U.S. Application Data
(60) Provisional application No. 61/535,207, filed on Sep. 15, 2011.

(51) Int. Cl. C23C 16/455; B05B 1/14

(52) U.S. Cl. 118/723 R; 239/548

(57) ABSTRACT

An apparatus for introducing gas into a processing chamber comprising one or more gas distribution tubes having gas-injection holes which may be larger in size, greater in number, and/or spaced closer together at sections of the gas introduction tubes where greater gas conductance through the gas-injection holes is desired. An outside tube having larger gas-injection holes may surround each gas distribution tube. The gas distribution tubes may be fluidically connected to a vacuum foreline to facilitate removal of gas from the gas distribution tube at the end of a process cycle.

### CROSS-REFERENCE TO RELATED APPLICATIONS

This application claims benefit of U.S. Provisional Patent Application Ser. No. 61/535,207 (APPM/16390L), filed Sep. 15, 2011, which is herein incorporated by reference.

### BACKGROUND OF THE INVENTION

1. Field of the Invention

Embodiments of the present invention generally relate to gas distribution tubes for providing a gas into a processing region.

2. Description of the Related Art

Plasma sources used in display and thin-film solar plasma enhanced chemical vapor deposition (PECVD) tools are typically parallel-plate reactors using capacitively coupled RF or VHF fields to ionize and dissociate process gases between plate electrodes. Next-generation flat-panel PECVD chambers include plasma reactors capable of processing two substrates at the same time by having two substrates in one “vertical” chamber and using “common” plasma and gas sources between the substrates. This approach not only increases the throughput of the system, but may also cut the cost of RF hardware and process gases (per throughput) as both gas and RF power are shared by two substrates when they are processed together.

The plasma in such PECVD reactors may be generated by an array of linear plasma sources placed between the two substrates, and process gases may be delivered from gas lines distributed over the substrate area. The gas lines may be in-plane with the plasma lines, which are typically placed in the mid-plane between the two substrates, or the gas lines may be placed and distributed closer to the substrates. The gas lines may comprise one or more feed tubes having openings through which gas is introduced into the processing region. In these systems, plasma and gas uniformity in a direction perpendicular to the plasma and gas lines is a challenge which may be resolved either by proper distribution of the plasma and gas lines or by modifying the mechanics of the process, i.e., scanning the substrate(s) by one or several plasma/gas lines or by a combination of the two. Uniformity along the lines, however, is also challenging and especially critical for cases when the lines are over one meter long, which includes many next-generation display and solar tools.

Another challenge to uniform gas distribution is the clogging of the apertures in gas distribution tubes as process residues deposit around the openings, blocking the flow of gas into the processing volume. The clogging of the apertures prevents the gas from flowing uniformly into the processing region. While larger holes in the tube are less prone to clogging, they compromise the uniformity of the gas feed by contributing to the pressure drop along the gas tube. This causes the flow of gas into the processing chamber to be non-uniform. If smaller holes are used, the holes contribute less to the pressure drop along the gas feed tube but clog more easily.

There is a need in the art to provide reactive gas through a gas feed tube to a chamber uniformly across a substrate while minimizing clogging as well as pressure drops along the tube.

### SUMMARY OF THE INVENTION

Embodiments of the present invention generally to gas distribution tubes used in a processing chamber.

In one embodiment, a gas distribution system is provided. The system comprises a gas distribution tube, wherein a source gas is fed into at least one portion of the gas distribution tube, and wherein the gas distribution tube has substantially equal source gas flow from each aperture along the gas distribution tube.

In another embodiment, a gas distribution system is provided comprising a gas distribution tube, wherein a source gas is fed into at least one portion of the gas distribution tube, and wherein the gas distribution tube has apertures which are spaced farther apart from one another the closer the aperture is to the at least one portion of the gas distribution tube where the gas is fed.

In another embodiment, a gas distribution tube is provided comprising an inner tube having apertures, wherein the inner tube is connected to a gas source, and an outer tube surrounding the inner tube, wherein the outer tube has apertures larger than the apertures of the inner tube.

In yet another embodiment, a processing chamber is provided comprising a gas source, a plasma source, a vacuum pump, a substrate support, and at least one gas distribution tube fluidically coupled to the gas source, wherein a source gas is fed into at least one portion of the gas distribution tube, and wherein the gas distribution tube has apertures which are smaller in size the closer the aperture is to the at least one portion of the gas distribution tube where the source gas is fed. The at least one gas distribution tube may further comprise an outer tube surrounding the gas distribution tube, wherein the outer tube has apertures larger than the apertures of the gas distribution tube. In another embodiment, the at least one gas distribution tube may be fluidically connected to a vacuum line coupled to the vacuum pump.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic representation of a processing system that can be used with one embodiment.

FIGS. 2A-2C are schematic representations of the processing chambers of FIG. 1.

FIG. 3 is a schematic cross-sectional top view of a processing chamber of FIG. 1.

FIG. 4A is a schematic cross-sectional view of a gas feed tube according to one embodiment over a substrate.

FIG. 4B is a schematic cross-sectional view of a gas feed tube according to one embodiment over a substrate.

FIG. 5A is a perspective view of a gas feed tube according to one embodiment.

FIGS. 5B and 5C are schematic cross-sectional views of different embodiments of the gas feed tube of FIG. 5A.

FIGS. 6A and 6B are schematic cross-sectional views of different embodiments of the gas feed tube of FIG. 5A.

FIG. 7 is a perspective view of a tube within a tube gas feed system according to one embodiment.

FIG. 8 depicts a graphical representation of the deposition from a gas distribution system according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to gas distribution tubes for providing a gas into a processing region, including gas distribution tube geometry and gas-injection hole distribution along the tube so that reactive gases can be fed into the area between the gas distribution tube and substrate uniformly along the length of the tube. Embodiments described herein can provide substantially equal gas flow such as no greater than 20% difference in flow per twelve inches of gas distribution tube length, with further embodiments of less than 10% difference in flow per six inches of gas distribution tube length.

In one embodiment, gas distribution tubes disposed between plasma lines and a substrate may have a small cross-section in order to minimize plasma shadowing. In other embodiments, the spacing of gas-injection holes along the gas distribution tubes may be larger at sections of the tubes where less gas outflow (and less pressure drop) is desired (such as in the vicinity of sections of the tube where the gas is fed). The spacing of gas-injection holes may be reduced at sections of the gas distribution tubes where more gas outflow is desired (such as towards the center of the gas distribution tube). In another embodiment, the size of holes in the gas distribution tubes may be smaller at sections of the tubes where less gas outflow is desired (such as sections of the tube where the gas is fed) and larger at sections of the tubes where more gas outflow is desired (such as towards the center of the gas distribution tube). Similarly, the number of holes in the gas distribution tubes may be smaller at sections of the tubes where less gas outflow is desired and larger at sections of the tubes where more gas outflow is desired. In one embodiment, the gas distribution system may comprise an inner gas distribution tube having holes which may be disposed within an outer tube having holes which are generally larger and which may be more spaced apart than the holes of the inner tube. The inner gas distribution tube may be coupled to one or more gas sources. The positioning, spacing, and number of holes on each gas distribution tube may be used to maintain uniform gas distribution while minimizing clogging of the holes.

Embodiments described herein address the issue of non-uniform deposition related to gas distribution in chambers such as large-area PECVD chambers using linear plasma-source technology, particularly non-uniformity in the axial direction (i.e., parallel to the lines). Although some of the embodiments herein are shown for a microwave powered plasma reactor, the proposed solution can be used: (i) for any plasma reactor using linear-plasma-source technology, e.g., microwave, inductive or capacitive; (ii) in any type of CVD system, vertical dual, or single substrate chambers, or horizontal single substrate chamber; (iii) in chambers using any deposition mode, the static or dynamic mode, and (iv) for other plasma technologies or applications, e.g., etching or resist-stripping, or reactive PVD.

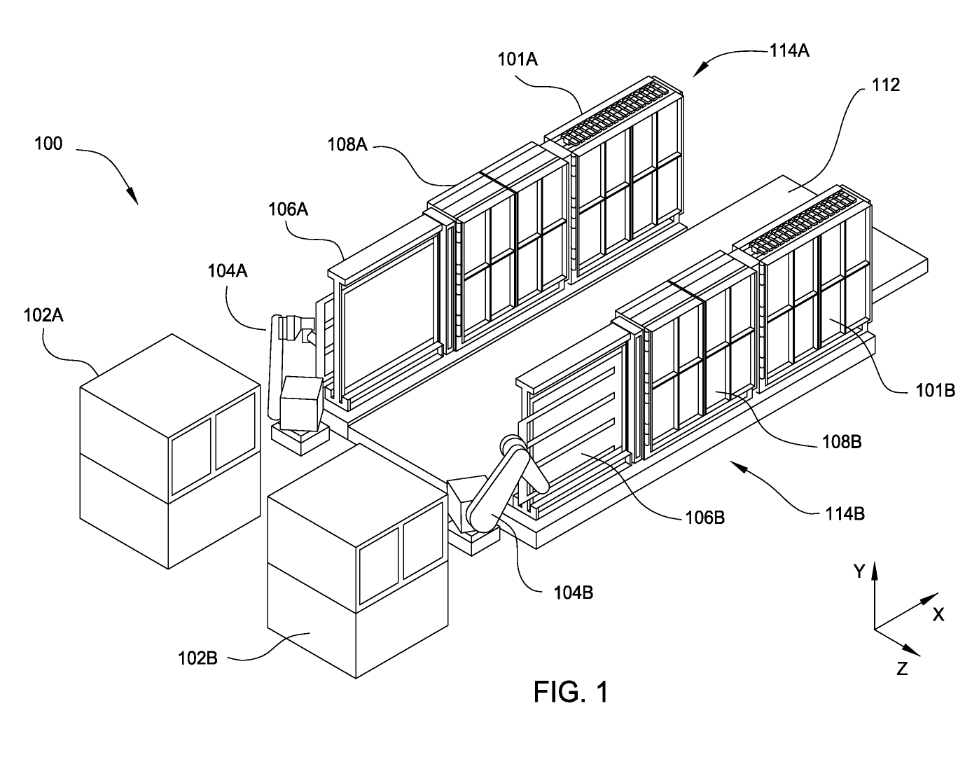

FIG. 1 is a schematic representation of a processing system that can be used with embodiments of the gas distribution tubes described herein. FIG. 1 is a schematic representation of a vertical, linear CVD system 100. The linear CVD system 100 may be sized to process substrates having a surface area of greater than about 90,000 cm² and able to process more than 90 substrates per hour when depositing a 2,000 Angstrom thick silicon nitride film. The linear CVD system 100 may include two separate process lines 114A, 114B coupled together by a common system control platform 112 to form a twin process line configuration/layout. A common power supply (such as an AC power supply), common and/or shared pumping and exhaust components and a common gas panel may be used for the twin process lines 114A, 114B. Each process line 114A, 114B may process more than 45 substrates per hour for a system total of greater than 90 substrates per hour. Although two process lines 114A, 114B are shown in FIG. 1, it is also contemplated that the system may be configured using a single process line or more than two process lines.

Each process line 114A, 114B includes a substrate stacking module 102A, 102B from which fresh substrates (i.e., substrates which have not yet been processed within the linear CVD system 100) are retrieved and processed substrates are stored. Atmospheric robots 104A, 104B retrieve substrates from the substrate stacking modules 102A, 102B and place the substrates into a dual substrate loading station 106A, 106B. It is to be understood that while the substrate stacking module 102A, 102B is shown having substrates stacked in a horizontal orientation, substrates disposed in the substrate stacking module 102A, 102B may be maintained in a vertical orientation similar to how the substrates are held in the dual substrate loading station 106A, 106B. The fresh substrates are then moved into dual substrate load lock chambers 108A, 108B and then to a dual substrate processing chamber 101A, 101B. The substrate, now processed, then returns through one of the dual substrate load lock chambers 108A, 108B to one of the dual substrate loading stations 106A, 106B, where it is retrieved by one of the atmospheric robots 104A, 104B and returned to one of the substrate stacking modules 102A, 102B.

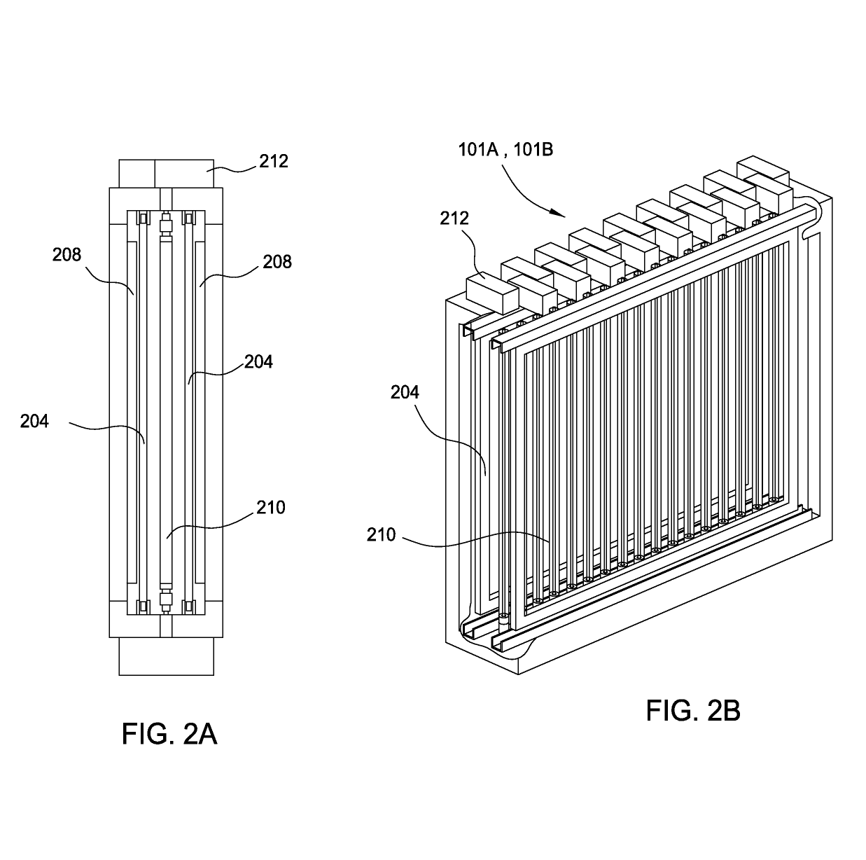

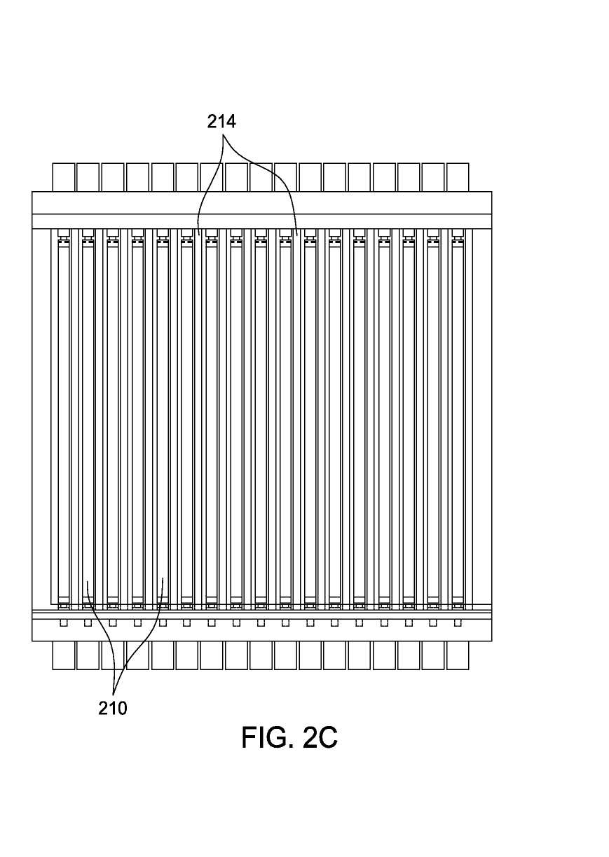

FIGS. 2A-2C are schematic representations of the dual substrate processing chambers 101A, 101B in FIG. 1. FIG. 3 shows a schematic cross-sectional top view of the dual substrate processing chambers 101A, 101B in FIG. 1. Referring to FIGS. 2A-2C, the dual substrate processing chambers 101A, 101B include a plurality of microwave antennas 210 disposed in a linear arrangement in the center of each dual substrate processing chamber 101A, 101B. The microwave antennas 210 extend vertically from a top of the processing chamber to a bottom of the processing chamber. Each microwave antenna 210 has a corresponding microwave power head 212 at both the top and the bottom of the processing chamber that is coupled to the microwave antenna 210. As shown in FIG. 2B, the microwave power heads 212 may be staggered due to space limitations. Power may be independently applied to each end of the microwave antenna 210 through each microwave power head 212. The microwave antennas 210 may operate at a frequency within a range of 300 MHz and 3 GHz. The metal antenna may be solid or hollow, with arbitrary cross-section (circular, rectangular, etc.) and with length much larger than its cross-sectional characteristic dimension(s); the antenna may be directly exposed to plasma or embedded in a dielectric (note: dielectric is understood as solid insulator, or solid insulator plus air/gas gap or gaps), and powered by RF power. The linear source can be powered at one end or at both ends, with one or two RF generators. Also, one generator can power one linear plasma source or several sources in parallel or in series, or in combination of both.

Each of the processing chambers is arranged to be able to process two substrates, one on each side of the microwave antennas 210. The substrates are held in place within the processing chamber by a substrate carrier 208 and a shadow frame 204. Gas introduction tubes 214 may be disposed between adjacent microwave antennas 210. Gas introduction tubes 214 may be made of any suitable, preferably noncorrosive material used for distributing gas, such as aluminum or stainless steel. The gas introduction tubes 214 extend vertically from the bottom to the top of the processing chamber parallel to the microwave antennas 210. The gas introduction tubes 214 permit the introduction of processing gases, such as silicon precursors and nitrogen precursors. While not shown in FIGS. 2A-2C, the processing chambers 101A, 101B may be evacuated through a pumping port (see 302A-302D in FIG. 3) located behind the substrate carriers 208.

FIG. 3 is a schematic cross-sectional top view of a dual substrate processing chamber 101A (which may be the same as dual substrate processing chamber 101B) of FIG. 1 having substrates 306 disposed inside and the gas introduction tubes 214 coupled to a vacuum foreline. The gas introduction tubes 214 are placed and distributed close to the substrates 306 disposed on substrate carriers 208. The connection points 302A-302D for dual substrate processing chamber 101A lead to a vacuum foreline. Because the connection points 302A-302D are disposed near the corners of the dual substrate processing chamber 101A, the dual substrate processing chamber 101A may be evacuated substantially uniformly in all areas of the dual substrate processing chamber 101A. If only one evacuation point were utilized, there may be greater vacuum near the evacuation point as compared to a location further away. It is contemplated that other evacuation connections are possible, including additional connections.

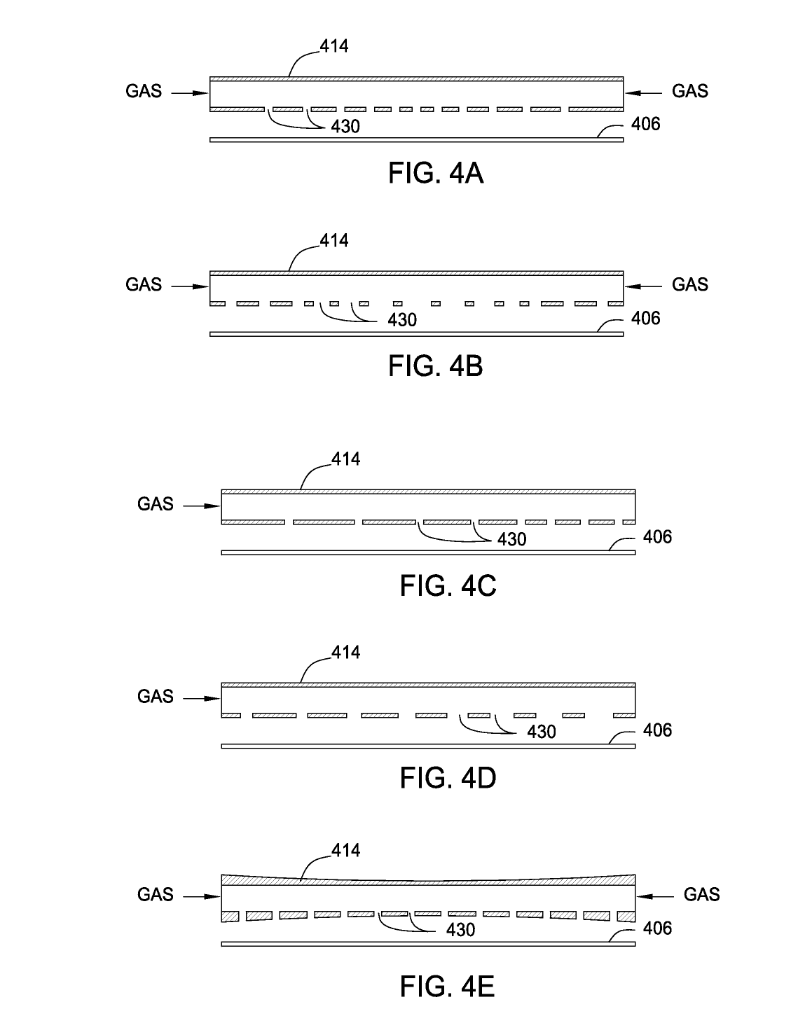

The gas introduction tubes 214 may be tubes of circular, oval, or rectangular cross-section(s) placed parallel to the substrate(s). The gas introduction tubes 214 are typically fed from both ends (e.g., at the top and bottom of in processing chamber in the case of the vertical processing chambers of FIGS. 2A and 2B), via feedthrough(s) in the chamber wall(s), and the gas-line plenum (inner section of the gas introduction tube 214) is connected to the process chamber through a number of gas-injection holes (see, e.g., 430 in FIG. 5A) distributed along the gas introduction tubes 214. In one embodiment, the processing gas or gases are fed into each gas introduction tube through a main feed tube or manifold (not shown) which is fluidically coupled to each gas introduction tube 214. The main feed tube or manifold may be fed by one or more gas sources. One or more control valves may be placed between the main gas tube or manifold and each gas introduction tube 214 in order to control the flow to each gas introduction tube 214. Therefore, the flow of gas into each gas introduction tube 214 may be varied depending on where in the processing chamber the gas introduction tube 214 is located (e.g., towards the center as opposed to the ends) or depending on the shape and size of the substrates processed in the chamber.

In one embodiment, the gas introduction tubes 214 have small cross-sections and a small outer surface area, so that plasma losses (the losses of charged particles due to plasma-wall interactions) and reactant losses (loss of radicals due to deposition on gas-line outer surfaces) are minimized and the power and gas-utilization efficiency of the process chamber is improved. A reduction of the outer surface area of the gas introduction tubes 214 also advantageously minimizes the frequency of chamber cleaning, cleaning-gas consumption and/or cleaning time because less material deposits on the gas introduction tubes 214. Therefore, peeling of film deposited on the gas introduction tubes 214 during processing is less likely to occur because less material gets deposited due to the reduced surface area and system throughput is improved.

For chamber configurations in which the gas introduction tubes 214 are not placed in the chamber in the same plane as the linear plasma sources (such as microwave antenna 210), but in a plane closer to the substrate, keeping the gas introduction tubes 214 thin also minimizes shadowing of the plasma. If the gas introduction tubes 214 are close to the substrate(s) and are too large in diameter, plasma density behind the gas introduction tubes 214 (in the shadows respective to the plasma line) can be significantly lower than in the open area (outside the shadow), and this can negatively affect process uniformity in a direction perpendicular to the gas introduction tubes 214.

The gas introduction tubes 214 should be thin enough to minimize the outer surface area and plasma shadowing, but not so thin as to compromise the strength of the gas introduction tubes 214, especially when they are long, as is the case in a linear-type large area plasma reactor. In some embodiments, the gas introduction tube may have a circular cross-section, a length of about 3 m and an outer diameter of about 0.5 inches and an inner diameter of about 0.25 inches.

Gas introduction tubes 214 having a small cross-section, such as a small inner diameter in the case of tubes with a circular cross-section, however, may have a low gas conductance inside the gas introduction tubes 214. Preferably, the gas conductance of gas-injection holes along the gas introduction tubes 214 is sufficiently small compared to the gas conductance in the gas introduction tubes 214 so as to have uniform gas distribution along the line. If the gas conductance of the gas-injection holes is large, more gas will tend to flow out of the gas introduction tubes 214 through the gas-injection holes into the processing chamber close to the gas-line feed(s) rather than travel through the entire length of the gas introduction tube 214. This will result in a non-uniform process. Therefore, to compensate for this non-uniformity, the size and number of gas-injection holes may be minimized, and the spacing between holes maximized, in order to minimize gas injection-hole conductance per unit length of gas-line. In one embodiment, the gas-injection holes of a gas introduction tube having a length of about 3 m may be circular and have a diameter of 16 mm. In another embodiment, the gas-injection holes of a gas introduction tube having a length of about 3 m may have diameters ranging from about 1 mm to about 14 mm. In some embodiments, all the gas-injection holes may have the same diameter. In other embodiments, the gas-injection holes may have varying diameters and constant spacing between gas-injection holes.

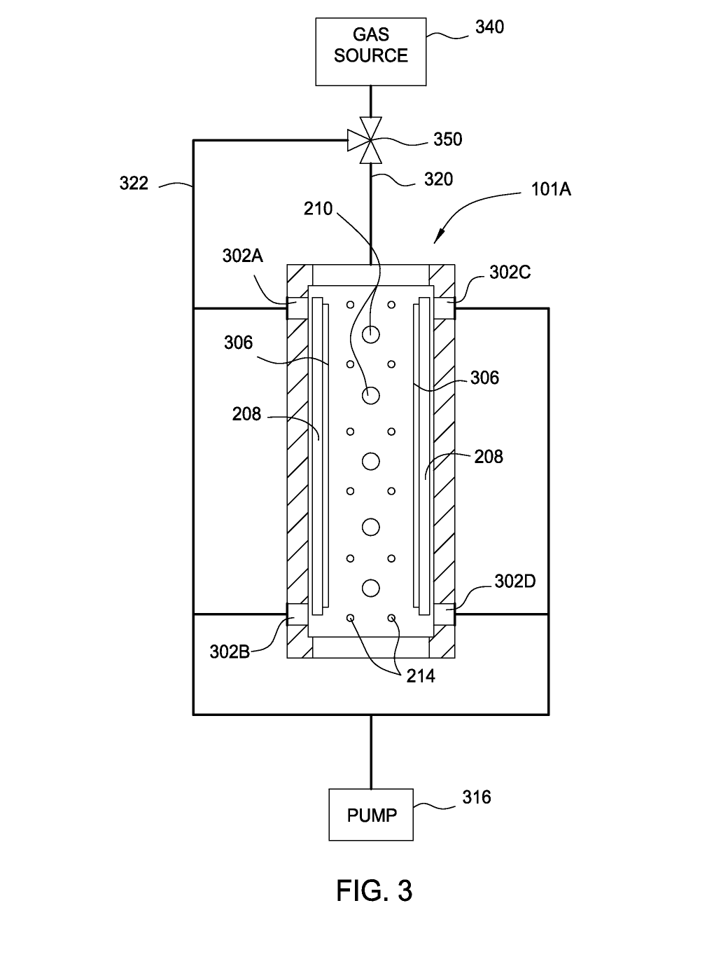

In certain embodiments, gas-injection conductance gradients may be achieved by varying the spacing and/or the size of the gas-injection holes along the gas introduction tubes 214. FIG. 4A is a schematic cross-sectional view of a gas introduction tube (having a gas feed at each end thereof) according to one embodiment in which the gas-injection conductance gradient is formed by varying the spacing of gas-injection holes 430. As shown in FIG. 4A, the gas-injection holes 430 along the gas introduction tube 414 may be spaced farther apart close to the gas feeds and may be spaced closer together towards the center of the gas introduction tube 414. This configuration allows less gas to escape the gas introduction tube 414 (through gas-injection holes 430) at sections thereof closer to the gas feeds, where the gas is at a higher pressure, thereby allowing more gas to flow towards the center of the gas introduction tube 414. The gas thereby flows out of gas-injection holes 430 more uniformly and results in improved deposition over substrate 406.

A gas-injection conductance gradient may also be achieved by varying the size of the gas-injection holes 430 along the gas introduction tube 414. FIG. 4B is a schematic cross-sectional view of a gas introduction tube (having a gas feed at each end thereof) according to one embodiment in which the gas-injection conductance gradient is formed by varying the size of gas-injection holes 430. As shown in FIG. 4B, the gas-injection holes 430 along the gas introduction tube 414 may be smaller in size (e.g., smaller diameter in the case of round holes) close to the gas feeds and larger in size towards the center of the gas introduction tube 414. This allows less of the gas to escape the gas introduction tube 414 closer to the feeds where it is at a higher pressure and more gas to flow out of the gas introduction tube 414 towards the center of the gas introduction tube 414. The gas thereby flows out of gas-injection holes 430 more uniformly and results in improved deposition over substrate 406.

Gas-injection conductance gradients may also be achieved by varying a combination of the spacing, number and size of the gas-injection holes 430. Although only one gas introduction tube is shown in FIGS. 4A-4B, it should be understood that gas conduction gradients may be similarly formed in gas-injection tubes in multiple gas line chambers (such as the linear CVD system 100 shown in FIG. 1) in order to achieve gas distribution uniformity. Furthermore, local gas conductances along the gas introduction tube(s) may be made to vary (by changing the spacing, number, and/or size of the gas-injection holes) from both ends toward the center of the gas introduction tube(s), or from one end to the other end of the gas introduction tube(s), depending on whether the gas lines are fed from both ends or only from one end. For example, FIG. 4C shows a gas introduction tube 414 fed with gas from one end only. The gas-injection holes 430 may be spaced further apart the closer they are to the end of the gas introduction tube 414 where the gas is fed. FIG. 4D shows a gas introduction tube 414 fed with gas from one end only. The gas-injection holes 430 may be smaller in size the closer they are to the end of the gas introduction tube 414 where the gas is fed, and larger in size the farther away they are from the end of the gas introduction tube 414 where the gas is fed. In another embodiment, the outer surface of gas introduction tube 414 may be brushed so that the thickness of the walls of the gas introduction tube 414 vary along the length of gas introduction tube 414. For example, as shown in FIG. 4E, the outer surface of gas introduction tube 414 (in which gas is fed from both ends thereof) may be brushed so that the outer surface of outer surface of gas introduction tube 414 facing the substrate 406 is concave. Therefore, gas-injection holes 430 may be longer (less gas conductance out of the gas-injection hole) the closer they are to the ends of the gas introduction tube 414 where the gas is fed, and shorter the farther away they are from the end of the gas introduction tube 414 where the gas is fed. If only one end of gas introduction tube 414 is fed with gas, the outer surface of gas introduction tube 414 may be brushed and tapered so that gas-injection holes 430 may be longer the closer they are to the end of the gas introduction tube 414 where the gas is fed, and shorter the farther away they are from the end of the gas introduction tube 414 where the gas is fed. In other embodiments, local gas conductances along the gas introduction tube(s) may be arranged non-uniformly depending on the need, such as offset process-chamber related asymmetries (pumping, substrate/stage edges, or inclined substrates in vertical chambers, etc.).

FIG. 5A illustrates a perspective view of a gas introduction tube 514 according to one embodiment. As shown in FIG. 5A, two rows of gas-injection holes 530 may be formed along the length of gas introduction tube 514, with more gas-injection holes 530 formed towards the center of gas introduction tube 514. The rows of gas-injection holes 530 face the substrate (not shown) and the gas-injection conductance gradient formed by the distribution of the gas-injection holes 530 ensures that the gas fed into gas introduction tube 514 does not escape gas introduction tube 514 near the ends thereof and reaches the center of the tube. Thus, the pressure drop along gas introduction tube 514 is minimized.

FIGS. 5B and 5C are schematic cross-sectional views of different embodiments of the gas introduction tube of FIG. 5A. The rows of gas-injection holes 530 may be formed at an angle A which may vary depending on the application. In one embodiment, angle A may be an angle chosen from a range from 30 to 60 degrees. In another embodiment, angle A may be an angle chosen from a range from 30 to 90 degrees. Although FIG. 5A shows two rows of gas-injection holes 530 in gas introduction tube 514, other embodiments may include gas introduction tubes having only one row of gas-injection holes, or three rows of gas-injection holes, or more. Any angle that could be used for two rows, could also be used for three or more rows. Further, when dealing with three or more rows, the angle of separation between rows need not be equal. Furthermore, the gas injection holes may be formed in other patterns, depending on the application, and such patterns may be regular or irregular.

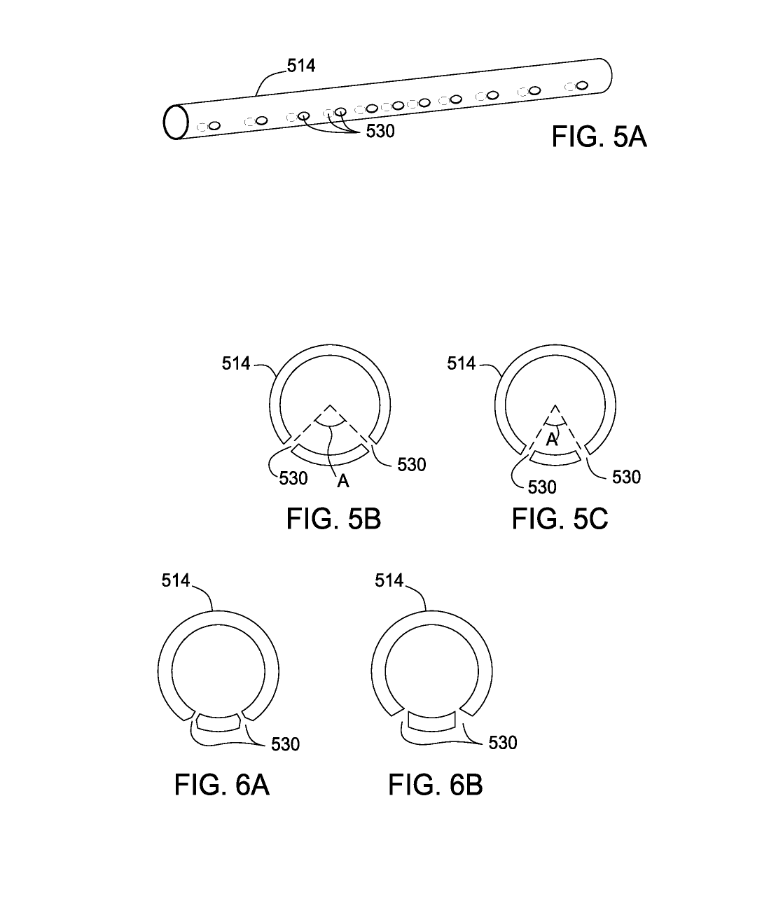

FIGS. 6A and 6B are schematic cross-sectional views of different embodiments of the gas feed tube of FIG. 5A. In some embodiments, the gas-injection holes 530 may be drilled such that the diameter of the hole changes throughout the thickness of gas introduction tube 514. In the embodiment shown in FIG. 6A, the diameter of the gas-injection hole may be greatest at the outer surface of the gas introduction tube 514, taper in towards the center of the thickness of the gas introduction tube 514, and become cylindrical as it reaches the inner surface of the gas introduction tube 514. The gas-injection holes 530 shown in FIG. 6B have a conical shape, with the diameter of the gas-injection hole gradually increasing from the inside surface of the gas introduction tube 514 to the outside surface thereof. Other shapes of gas-injection holes may be used.

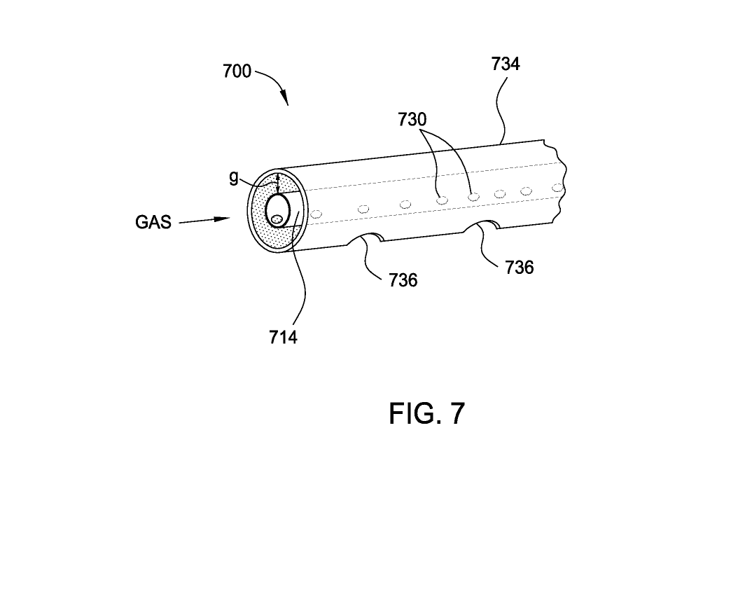

FIG. 7 shows another embodiment of a gas introduction tube 700 including inner gas introduction tube 714 positioned within an outer gas introduction tube 734. A gas supply (not shown) may be coupled to the inner gas introduction tube 714. Inner gas introduction tube 714 may be made of any suitable, preferably noncorrosive material used for distributing gas, such as aluminum or stainless steel, and may have an outer diameter small enough such that it can be disposed inside the outer gas introduction tube 734 with a gap g between the two tubes. The inner gas introduction tube 714 includes one or more gas-injection holes 730 and the outer gas introduction tube 734 includes one or more gas-injection holes 736. The gas-injection holes 730 allow gas from inside the inner gas introduction tube 714 to escape the inner gas introduction tube 714 into the volume between the inner gas introduction tube 714 and the outer gas introduction tube 734. The gas-injection holes 736 allow gas to escape the outer gas introduction tube 734 into the processing region.

Gas conductance gradients may be used on one or both inner gas introduction tube 714 and outer gas introduction tube 734 to improve gas distribution uniformity, in much the same way as explained above. The smaller the gas-injection holes 730, the more uniform the flow of gas out of inner gas introduction tube 714. The smaller gas-injection holes 730 minimize pressure drops along the length of the inner gas introduction tube 714 and create a plenum that allows pressure to build up within the inner gas introduction tube 714. Therefore, gas escaping the inner gas introduction tube 714 is generally at the same flowrate at all locations along the inner gas introduction tube 714. The small gas-injection holes 730 also prevent plasma in the processing region from entering the plenum within the inner gas introduction tube 714. In order to prevent clogging of the small gas-injection holes 730, the outer gas introduction tube 734 is disposed around inner gas introduction tube 714 to shield inner gas introduction tube 714 and gas-injection holes 730 from plasma deposition. By maintaining a pressure differential of, e.g., a factor of two, between the inside of the inner gas introduction tube 714 and the processing volume, gas is prevented from moving into inner gas introduction tube 714, and plasma losses (the losses of charged particles due to plasma-gas line wall interactions) can be minimized.

In order to improve the plenum formed within the inner gas introduction tube 714, the number of gas-injection holes 730 may be minimized so that sufficient pressure within inner gas introduction tube 714 is maintained. In other embodiments, the number of gas-injection holes 730 in inner gas introduction tube 714 may be reduced along sections of the tube closest to the gas feeds (e.g., FIG. 7 shows less gas-injection holes towards the end where the gas is being introduced). This may be accomplished by spacing the gas-injection holes 730 further apart at sections of inner gas introduction tube 714 where less gas outflow is desired. In another embodiment, gas outflow along sections of the inner gas introduction tube 714 may be varied by making the gas-injection holes 730 smaller at sections of inner gas introduction tube 714 where less gas outflow is desired. In other embodiments, different shapes and sizes of gas-injection holes 730 may be used to vary the outflow of gas along the length of the inner gas introduction tube 714.

The positioning, spacing, shape and size of the gas-injection holes 730 may vary throughout the length of inner gas introduction tube 714 as desired or needed depending on the configuration of the tubes, the processing chamber and the deposition process. Some sections may have regularly repeating gas-injection hole patterns, and other sections may have irregularly spaced, sized or shaped gas-injection holes. For example, reduction of the number and/or size of gas-injection holes 730 may be at one or both ends of the inner gas introduction tube 714, or one end can vary from the other, depending on whether the gas lines are fed from both ends or only from one end. They can also be arranged non-uniformly for special needs, e.g., offset process-chamber related asymmetries (pumping, substrate/stage edges, or inclined substrates in vertical chambers, etc.). The gas-injection holes 736 on outer gas introduction tube 734 may similarly vary in number, spacing, size and shape depending on the configuration of the tubes, the processing chamber and the deposition process.

Between processing cycles, it may be difficult to evacuate the plenum formed within the gas distribution tube because the length of the gas distribution tube and the small size and number of the gas-injection holes reduce the rate of leakage of gas from the gas introduction tube. In order to reduce clean-out time in between cycles and improve process efficiency, the gas introduction tubes 214 may be coupled to the vacuum foreline to facilitate and accelerate removal of gas remaining inside the gas introduction tube.

The higher the pressure within the gas introduction tubes 214, the more difficult it may be to cycle the processing chamber (which may involve changing the processing gases) because the gas introduction tubes 214 may have a high gas density that must be evacuated before the next cycle. Even though the chamber may be evacuated using vacuum pump 316, it may take a long time for the gas inside the gas introduction tubes 214 to leak out due to the restricted flow as a result of the small diameters of gas-injection holes and the reduced number of gas-injection holes. For example, when a process terminates and it is necessary to exchange gases quickly, gas remaining in the gas introduction tubes 214 may take a long time to leak out to an acceptable minimum level. This delay may be more critical depending on the process gases used, particularly amorphous silicon. In order to facilitate and expedite the removal of gas from the gas introduction tubes 214, a three-way valve 350 may be installed on a gas line 320 which couples the gas introduction tubes 214 of the processing chamber to the gas source 340. The three-way valve 350 may also be coupled to a line 322 fluidly coupled to the vacuum foreline leading to the vacuum pump 316. Once a processing cycle ends, the vacuum pump 316 may be used to pump gas out of processing chamber as well as the gas introduction tubes 214. During processing, the three-way valve 350 may close flow to line 322 so that there is gas flow only between the processing chamber and the gas source 340. Such three-way valves may be placed as close to the gas source 340 as practical, to minimize the volume of the unvented gas delivery line (between the three-way valve and the gas source 340). Other valve combinations and configurations may also be used to divert gas flow in the same way as the three-way valve 350.

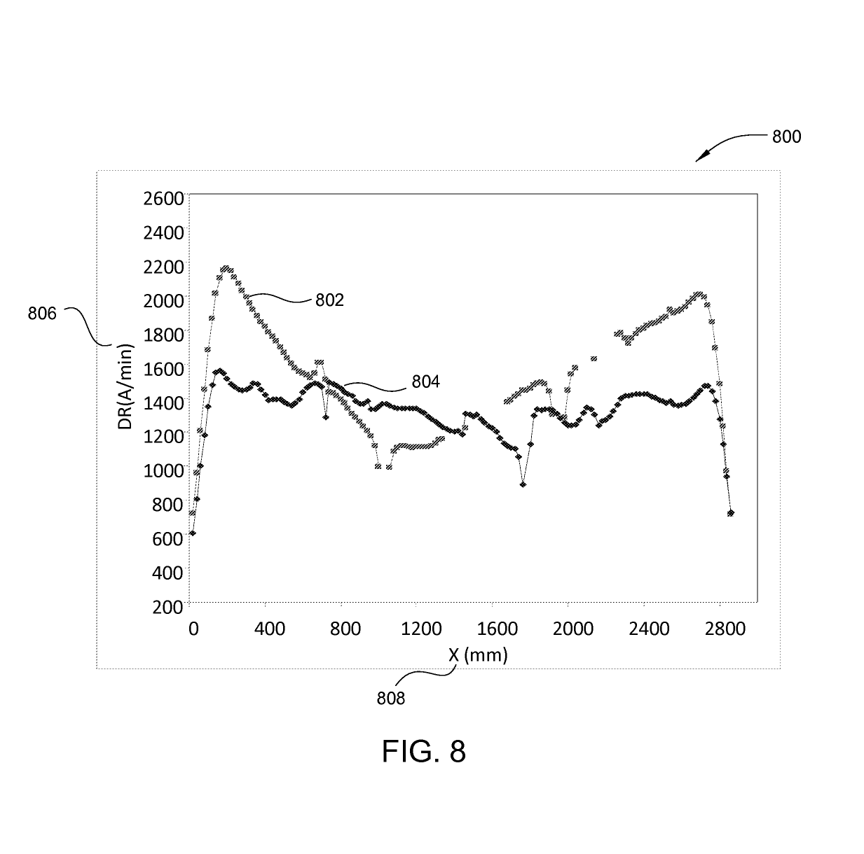

FIG. 8 depicts a graphical representation of the deposition from a gas distribution system according to one embodiment. FIG. 8 shows a graph 800 with deposition rate 806, as measured in Å/min., over substrate surface position 808, as measured in mm from an edge of the substrate. In this example, deposition by a standard gas distribution tube with no alterations to gas-injection hole placement (non-taped gas line 802) is compared to deposition by gas distribution tube with gas-injection holes occluded with increasing frequency as the gas distribution tube gets closer to the gas line (taped gas line 804). Gas-injection hole placement was simulated by Kepton tape placed over the gas-injection holes to prevent flow from the occluded gas-injection holes of the gas distribution tube. The non-taped tube had no gas-injection holes occluded by tape. The taped tube had gas-injection holes occluded to simulate a gas distribution tube with gas-injection holes of decreasing pitch between them at more distal points from the gas lines. As there are two gas lines in this embodiment, there were more available (non-occluded) gas-injection holes in the center of the gas distribution tube than there were at the gas line connection points.

Ammonia (NH₃) and silane (SiH₄) were introduced toward the substrate in the presence of an argon (Ar) plasma. The flow rates of all gases were maintained constant between the non-taped tube and the taped tube as was the power source and rate for plasma production. Further, flow rates to each side of the gas distribution tube were maintained constant to assure that the peaks and troughs reflect expected distribution of the gas within the gas distribution tube.

The non-taped tube shows standard peaks of deposition approaching 2200 Å/min at the gas entry points, which correspond to the 100 mm and 2700 mm points on the X axis of the graph. The pressure and subsequent deposition of the non-taped tube falls to as low as approximately 1000 Å/min as the gas travels the length of the tube.

The taped tube shows marked improvement in uniform deposition rate over the non-taped tube. Peaks which are normally formed at the gas entry points are diminished to around 1500 Å/min with the center point deposition reaching a minimum of about 1000 Å/min. Though the trough near the center still exists, the overall average of the deposition is much more uniform across the length of the gas distribution tube. As such, alteration of the hole pattern can provide a more uniform distribution of gas from the tube for deposition on the substrate.

Not to be bound by theory, it is believed that poor deposition uniformity can be created by non-uniform gas pressure inside the gas distribution tube. Gas pressure is believed to be affected by the size of the holes, the position of the holes, the method of gas delivery to the tube and the number of holes among other factors. As such, it is believed that by changing either hole position, size of holes or number of holes, the pressure along the gas distribution tube or by including a second tube to diffuse the effects of differential pressure, the deposition can be made more uniform than by traditional gas distribution tube designs.

As explained above, although FIG. 1 shows a vertical chemical vapor deposition (CVD) chamber in which the substrates are disposed vertically and gas distribution tubes run horizontally to an x-y plane, the embodiments described herein are not limited to the chamber configuration of FIG. 1. For example, the gas distribution tubes may be used in other CVD chambers in which the substrates are supported in a horizontal position substantially parallel to the ground.

While the foregoing is directed to embodiments of the present invention, other and further embodiments of the invention may be devised without departing from the basic scope thereof, and the scope thereof is determined by the claims that follow.

1. A gas distribution system, comprising:
a gas distribution tube having one or more source gas introduction ports and a plurality of apertures, wherein a source gas is fed into at least one portion of the gas distribution tube, and wherein the gas distribution tube has substantially equal source gas flow from each aperture along the gas distribution tube.

2. The gas distribution system of claim 1, wherein the apertures are smaller in size the closer the aperture is to the one or more source gas introduction ports.

3. The gas distribution system of claim 1, wherein the diameter of the apertures is graded from smaller to larger as measured from the inside of the gas introduction tube to the outside of the gas introduction tube.

4. The gas distribution tube of claim 1, wherein the wall of the gas distribution tube is thicker at portions of the tube that are closer to the one or more source gas introduction ports.

5. The gas distribution tube of claim 1, wherein the gas distribution tube has more than one aperture at each aperture position in the gas distribution tube.

6. The gas distribution tube of claim 5, wherein the gas distribution tube has two apertures at each aperture position in the gas distribution tube and the apertures are separated from 30 degrees to 60 degrees from one another.

7. The gas distribution system of claim 1, further comprising:
an outer tube surrounding the gas distribution tube, wherein the outer tube has apertures therethrough that are larger than the apertures of the gas distribution tube.

8. A gas distribution system comprising:
a gas distribution tube, wherein a source gas is fed into at least one portion of the gas distribution tube, and wherein the gas distribution tube has apertures which are spaced farther apart from one another the closer the aperture is to the at least one portion of the gas distribution tube where the gas is fed.

9. The gas distribution system of claim 8, wherein the size of the apertures is graded from smaller to larger as measured from the inside of the gas introduction tube to the outside of the gas introduction tube.

10. The gas distribution tube of claim 8, wherein the wall of the gas distribution tube is thicker at portions of the tube that are closer to the one or more source gas introduction ports.

11. The gas distribution tube of claim 8, wherein the gas distribution tube has more than one aperture at each aperture position in the gas distribution tube.

12. The gas distribution tube of claim 11, wherein the gas distribution tube has two apertures at aperture position in the gas distribution tube and the apertures are separated from 30 degrees to 60 degrees from one another.

13. The gas distribution system of claim 8, further comprising:
an outer tube surrounding the gas distribution tube, wherein the outer tube has apertures larger than the apertures of the gas distribution tube.

14. A processing chamber comprising:
a gas source;
a plasma source;
a vacuum pump;
a substrate support; and
at least one gas distribution tube fluidically coupled to the gas source, selected from the group consisting of:
a gas distribution tube having one or more source gas introduction ports, wherein a source gas is fed into at least one portion of the gas distribution tube, and wherein the gas distribution tube has apertures which are smaller in size the closer the aperture is to the at least one portion of the gas distribution tube where the gas is fed; and
a gas distribution tube, wherein a source gas is fed into at least one portion of the gas distribution tube, and wherein the gas distribution tube has apertures which are spaced farther apart from one another the closer the aperture is to the at least one portion of the gas distribution tube where the gas is fed.

15. The processing chamber of claim 14, wherein the at least one gas distribution tube further comprises an outer tube surrounding the gas distribution tube, wherein the outer tube has apertures larger than the apertures of the gas distribution tube.

16. The processing chamber of claim 14, wherein the at least one gas distribution tube is fluidically connected to a vacuum line coupled to the vacuum pump.

17. The processing chamber of claim 14, wherein the apertures comprise a conical shape, wherein the size of the conical shape is graded from smaller to larger as introduction tube.

18. The processing chamber of claim 17, wherein the apertures comprise a cylindrical shape connected with the smaller end of the conical shape.

19. The processing chamber of claim 14, wherein the wall of the gas distribution tube is thicker at portions of the tube that are closer to the one or more source gas introduction ports.

20. The processing chamber of claim 14, wherein the gas distribution tube has more than one aperture at each aperture position in the gas distribution tube.
